(19) United States
(12) Patent Application Publication
(10) Pub. No.: US 2001/0039128 A1
(43) Pub. Date: Nov. 8, 2001

(54) Method of connecting IC package to IC contactor with weaker force and IC contactor for such method

(76) Inventors: Masaru Tateishi, Kawasaki (JP); Toshihisa Watanabe, Kawasaki (JP)

Correspondence Address: ARMSTRONG, WESTERMAN, HATTORI, McLELAND & NAUGHTON, Suite 1000, 1725 K Street, N.W., Washington, DC, 20006, US

(21) Appl. No.: 09/731,755

(22) Filed: Dec. 8, 2000

(30) Foreign Application Priority Data
May 2, 2000 (JP) 2000-133764

(51) Int. Cl. H05K 1/00

(52) U.S. Cl. 439/71

(57) ABSTRACT

A method of electrically connecting protrusion electrodes formed on an IC package to contact pins of an IC contactor is provided, which method includes the steps of (a) receiving and holding the protrusion electrodes by the contact pins, and (b) applying pressing force from outside of the contact pins to the protrusion electrodes so that the protrusion electrodes are held more firmly by the contact pins than in the step (a).

### BACKGROUND OF THE INVENTION

1. Field of the Invention

The present invention generally relates to methods of connecting IC packages to IC contactors and IC contactors for such methods, and more particularly to a method of connecting a semiconductor device (hereinafter referred to as an IC package) including protrusion electrodes such as solder balls to an external test apparatus for making an electrical test on the semiconductor device and an IC connector for such a method.

Recently, there has been provided an IC package employing protrusion electrodes such as solder balls as external connection electrodes, such as an IC package of a ball grid array (BGA) type, for the downsizing purpose of the IC packages.

In order to achieve further downsizing of the IC packages, it is also required of the IC package including the protrusion electrodes to meet a demand for higher density and higher speed, thus causing pitches between electrodes to be narrower and the protrusion electrodes to be arranged with higher density and finer pitches.

On a finished IC package, a characteristic test is made to see if the IC package shows a predetermined characteristic. Before the test is made, the IC package is mounted in an IC contactor to be electrically connected to an external test apparatus. Therefore, an IC package connection method and an IC contactor should also comply with a higher-density arrangement of protrusion electrodes with finer pitches. Further, since strength of an individual protrusion electrode is extremely reduced because of such an arrangement, there is a strong demand for a method which secures an electrical connection of an IC package with an external apparatus without causing damage to the protrusion electrodes of the IC package.

2. Description of the Related Art

A description will be given, with reference to the accompanying drawings, of conventional IC package connection methods. FIGS. 1A through 1C show contact pins which are employed in conventional IC contactors.

FIG. 1A shows conventional contact pins 10, of one of which a description will be given for the convenience thereof in the following. According to FIG. 1A, the contact pin 10, which includes a couple of leaf springs 11 and 12, connects an IC package 1 having solder balls 2 on its lower portion to an IC contactor base 4 and a wiring board 5 for external connection of an IC contactor.

According to a connection method of FIG. 1A, the top end portion of the leaf spring 12 is moved away from the solder ball 2 by moving leftward a leaf spring moving member 13. When receiving the solder ball 2 of the IC package 1, the top end portion of the leaf spring 12 is first moved away from the solder ball 2 and then is moved back so that the solder ball 2 is held by the leaf springs 11 and 12.

FIG. 1B shows a conventional contact pin 20, which includes an upper plunger 21, a coil spring 22, and a lower plunger 23. The upper plunger 21 is pressed onto the solder ball 2 and the lower plunger 23 is connected to an electrode pad 6 formed on the wiring board 5 by the coil spring 22, which operates in upward and downward directions.

According to a connection method of FIG. 1B, the top portion of the upper plunger 21 is formed to have a cone-like concave portion so as to contact the solder ball 2 by resilient force of the coil spring 22.

FIG. 1C shows a conventional contact pin 30, which is provided in an upright position on the wiring board 5. The contact pin 30 includes a separation groove 31 to deform elastically. Japanese laid-open patent application No. 6-191951, for example, discloses such a contact pin.

According to a connection method of FIG. IC, when the solder ball 2 is connected to the contact pin 30, the contact pin 30 is pressed onto the surface of the solder ball 2 so that the top end portion of the contact pin 30 elastically deforms outward.

However, the prior art employing the above-described conventional methods of connecting the IC packages with the IC contactors cannot keep up with the recent trend toward higher-density and higher-speed IC packages.

In other words, according to the IC contactor which employs the contact pin 10 shown in FIG. 1A, each of the leaf springs 11 and 12 has to have a certain length so that the leaf spring 12 can be smoothly moved. Therefore, an inductance of the contact pin 10 is increased, which prevents the IC contactor from complying with a higher-density IC package. Further, the leaf spring 12 of the IC contactor is required to be moved, which makes it difficult to automate the connection method.

According to an IC contactor which employs the contact pin 20 shown in FIG. 1B, the contact pin 20 is supposed to rub against the solder ball 2 to break an oxide film formed on the surface of the solder ball 2 so that the IC contactor is connected to the IC package 1. However, such wiping may not properly be performed, thus causing a poor connection therebetween. In order to avoid such a situation, the coil spring 22 is required to generate a certain amount of load such that the upper plunger 21 contacts the solder ball 2 with sufficient force. Such an IC contactor requires pressing force of approximately 30 to 40 g per contact pin. Therefore, in the case of an IC package having more than hundreds of solder balls arranged thereon, too much load is applied from the contact pins 20 to the IC package, thus causing damages thereto. Particularly, in the case of an IC package of the BGA type with a cupper cap and a large number of pins, the cupper cap may be deformed by a great pressing load so that chip-cracks may be produced inside the IC package.

According to an IC contactor which employs the contact pin 30 shown in FIG. 1C, considering variations in the size of the solder ball 2, the separation groove 31 has to be designed to have a width narrowed to some extent so that a connection between an IC package and the IC contactor is reliably established. Therefore, the IC package is required to be pressed firmly onto the contact pins 30, which may cause a problem of overload as in the case of the IC contactor employing the contact pin 20 shown in FIG. 1B.

### SUMMARY OF THE INVENTION

It is a general object of the present invention to provide a method of connecting an IC package to an IC contactor and an IC contactor for such a method in which the above-described disadvantages are eliminated.

A more specific object of the present invention is to provide a method of reliably connecting an IC package to an IC contactor with weaker force and an IC contactor for such a method.

The above objects of the present invention are achieved by a method of electrically connecting protrusion electrodes formed on an IC package to contact pins of an IC contactor, which method includes the steps of (a) receiving and holding the protrusion electrodes by the contact pins, and (b) applying a pressing force from outside of the contact pins to the protrusion electrodes so that the protrusion electrodes are held more firmly by the contact pins than in the step (a).

According to the above-described method, the connections between the contact pins and the protrusion electrodes can be firmer with less pressing force.

The above objects of the present invention are also achieved by an IC contactor to which an IC package is connected, which IC contactor includes: a contact base; contact pins provided on the contact base so as to correspond to protrusion electrodes formed on the IC package, the contact pins including first plungers which include holding portions provided on tops thereof for holding the protrusion electrodes and second plungers which contact a base for external connection; and first pressing units which apply a pressing force to the holding portions from outside thereof.

According to the above-described IC contactor, the protrusion electrodes can be firmly held by the holding portions with the pressing force of the first pressing units applied to the holding portions.

### BRIEF DESCRIPTION OF THE DRAWINGS

Other objects, features and advantages of the present invention will become more apparent from the following detailed description when read in conjunction with the accompanying drawings, in which:

FIGS. 1A through 1C are diagrams showing contact pins for conventional IC contactors;

FIG. 2 is a schematic diagram of a structure of a contact pin for an IC contactor according to a first embodiment of the present invention;

FIGS. 3A through 3C are diagrams showing adoptable examples of a top end holding portion for the contact pin of FIG. 2;

FIGS. 4A through 4C are diagrams showing further examples of the top end holding portion for the contact pin of FIG. 2;

FIG. 5A is a sectional view of an IC contactor and an IC package in a state immediately after the IC package is mounted in the IC contactor according to a second embodiment of the present invention;

FIG. 5B is an enlarged sectional view of a solder ball, a top end holding portion, and a cradle, showing their positional relations in the state shown in FIG. 5A;

FIG. 6A is a sectional view of the IC contactor and the IC package in a state in which the solder balls of the IC package are placed on the respective top end holding portions according to the second embodiment of the present invention;

FIG. 6B is an enlarged sectional view of the solder ball, the top end holding portion, and the cradle, showing their positional relations in the state shown in FIG. 6A;

FIG. 7A is a sectional view of the IC contactor and the IC package in a first holding state in which the solder balls are held by the respective top end holding portions according to the second embodiment of the present invention;

FIG. 7B is an enlarged sectional view of the solder ball, the top end holding portion, and the cradle, showing their positional relations in the state shown in FIG. 7A;

FIG. 8A is a sectional view of the IC contactor and the IC package in a second holding state in which the solder balls are held more firmly by the respective top end holding portions than in the first holding state according to the second embodiment of the present invention; and

FIG. 8B is an enlarged sectional view of the solder ball, the top end holding portion, and the cradle, showing their positional relations in the state shown in FIG. 8A.

### DETAILED DESCRIPTION OF THE PREFERRED EMBODIMENTS

A description will now be given, with reference to the accompanying drawings, of embodiments of the present invention.

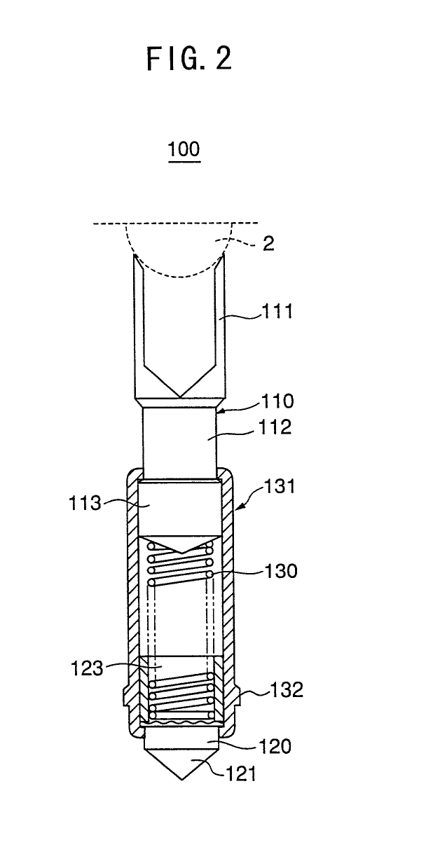

FIG. 2 is a schematic diagram showing a structure of a contact pin 100 used for an IC contactor according to a first embodiment of the present invention. The IC contactor has a plurality of the contact pins 100 provided in positions corresponding to a number of protrusion electrodes (solder balls) arranged on the surface of an IC package. FIG. 2 shows one of those contact pins 100.

According to FIG. 2, the contact pin 100 includes an upper plunger 110, a lower plunger 120, and a coil spring 130, which is provided between the upper and lower plungers 110 and 120 as a pressing unit.

The coil spring 130, which is provided in a sleeve 131, presses a base portion 113 of the upper plunger 110 and a base portion 123 of the lower plunger 120 so as to separate the base portions 113 and 123. Therefore, if an external force is applied in a downward direction to the upper plunger 110, the upper plunger 110 in the state shown in FIG. 2 can be pressed down to the side of the lower plunger 120.

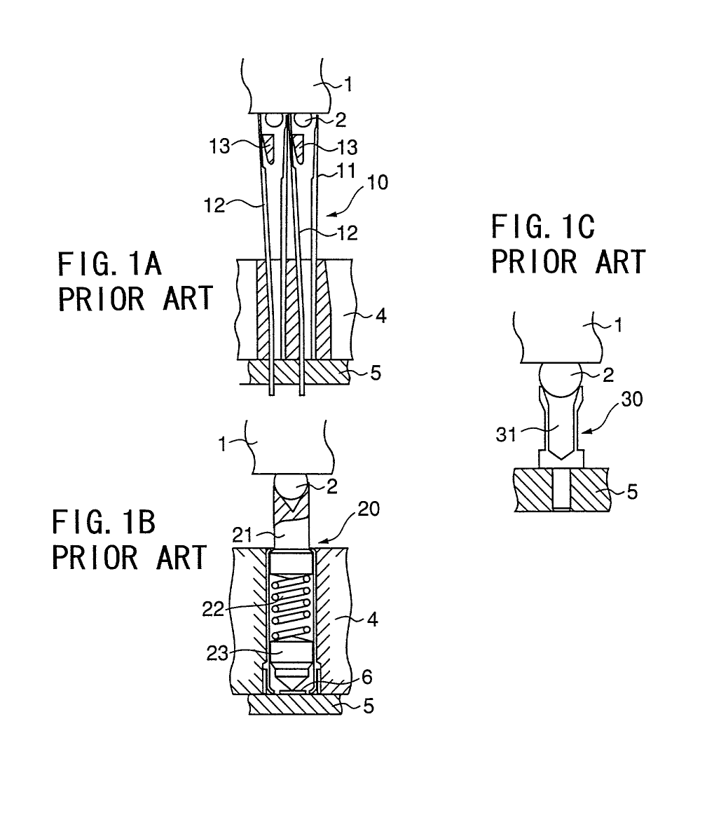

The lower end portion 121 of the lower plunger 120 comes into contact with an electrode pad (not shown) formed on a wiring board (not shown) as in the case shown in FIG. 1B. A top end holding portion 111 having a slit structure is formed on the upper plunger 110 to hold the solder ball 2. The top end holding portion 111, which is formed of an elastic member, is widened in a radial direction (leftward and rightward directions in FIG. 2) so as to receive the solder ball 2. The top end portion of the top end holding portion 111 is tapered inward so that the solder ball 2 can be received easily.

Elastic force (holding force) of the above-described top end holding portion 111 is set to be weak compared with the pressing force of the coil spring 130. In other words, since a force which presses the solder ball 2 into the top end holding portion 111 opposes the pressing force of the coil spring 130, it is recommended that the elastic force of the top end holding portion 111 and the pressing force of the coil spring 130 be set so that the top end portion 111 firmly receives the solder ball 2 when the pressing force of the coil spring 130 is applied. In the process of thus pressing the solder ball 2 into the top end holding portion 111, the top end portion of the top end holding portion 111 rubs against the surface of the solder ball 2 so that wiping is performed.

The upper plunger 110 includes a connecting portion 112 between the top end holding portion 111 and the base portion 113 of the upper plunger 110, and moves up and down within a length of the connecting portion 112, so that the top end holding portion 111 and the base portion 113 of the upper plunger 110 approach or are separated from each other.

The sleeve 131 has flanges 132 formed on the outer surface thereof so that the contact pin 100 is fixedly inserted into a through hole 204 formed in a contact base 205 as described later. The contact pin 100 is positioned by inserting the contact pin 100 into the through hole 204 from the lower opening thereof, so that the contact pin 100 is provided in an upright position on the contact base 205.

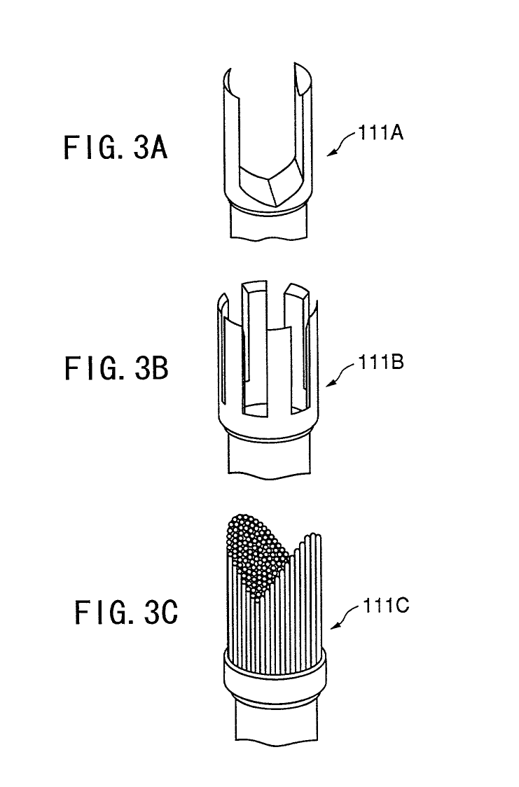

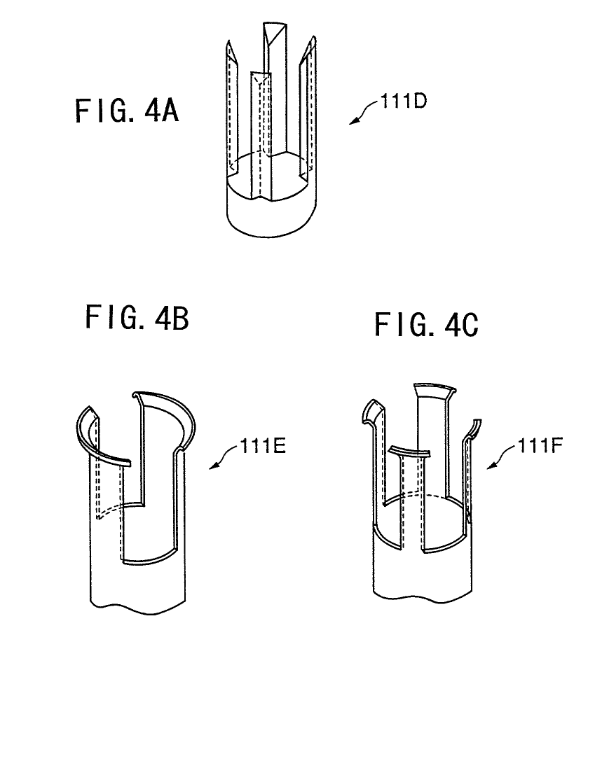

FIGS. 3A through 4C show adoptable examples of the shape of the top end holding portion 111.

FIG. 3A shows a top end holding portion 111A, which has the same slit structure as the top end holding portion 111 shown in FIG. 2. The top end holding portion 111A includes the top end portion thereof, which contacts a solder ball. The top end portion is shaped to form a portion of a spherical surface. According to the top end holding portion 111A having this structure, wiping can be performed with the solder ball being firmly received.

FIG. 3B shows a top end holding portion 111B, which has a split structure and includes six pin portions. The top end portion of the top end holding portion 111B is tapered. Also according to the top end holding portion 111B having this structure, wiping can be performed with a solder ball being firmly received.

FIG. 3C shows a top end holding portion 111C, in which a plurality of wires are planted to form a V shape as a whole. Also according to the top end holding portion 111C having this structure, wiping can be performed with a solder ball being firmly received. As a variation of the top end holding portion 111C, the wires can be planted to form a mortar-like shape.

FIG. 4A shows a top end holding portion 111D, which has a split structure and includes four pin portions. Each of the pin portions is shaped like a triangle pole so that a solder ball is held at each contact point by the pin portions. Each contact point is on the ridgeline of each pin portion. FIG. 4B shows a top end holding portion 111E. The peripheral portion of the top end portion thereof is extended outward so that the solder ball can be received with more ease. FIG. 4F shows a top end holding portion 111F, which has a split structure and includes four pin portions. The peripheral portion of the top end portion thereof is extended outward so that the solder ball can be received with more ease. Also according to each of the top end portions 111D through 111F, the solder ball can be received easily and a wiping effect can be provided to the surface of the solder ball.

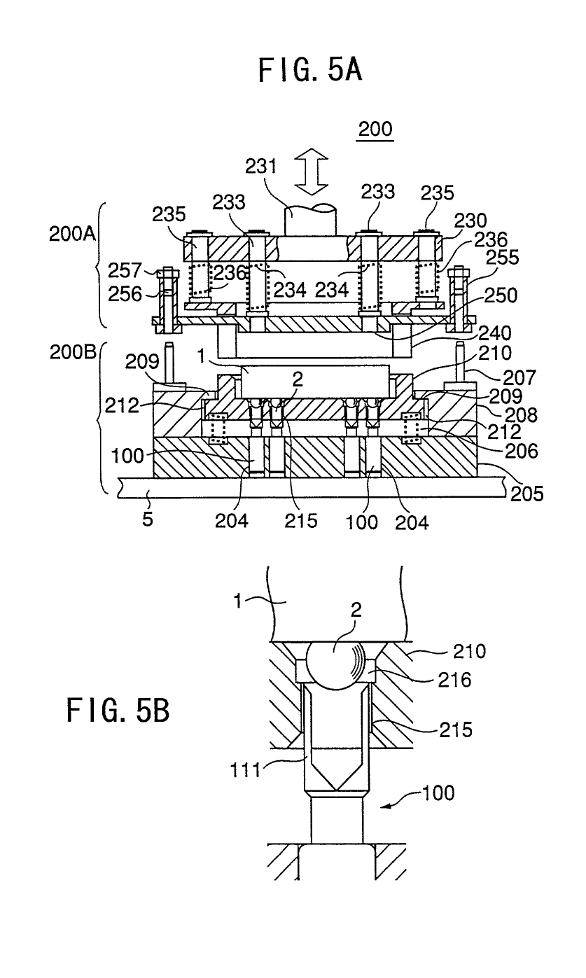

Next, a description will be given, according to a second embodiment of the present invention, of steps of connecting an IC package to an IC contactor with reference to FIGS. 5A through 8B, which shows an overall structure of an IC contactor 200 employing the contact pins 100, one of which is shown in FIG. 2.

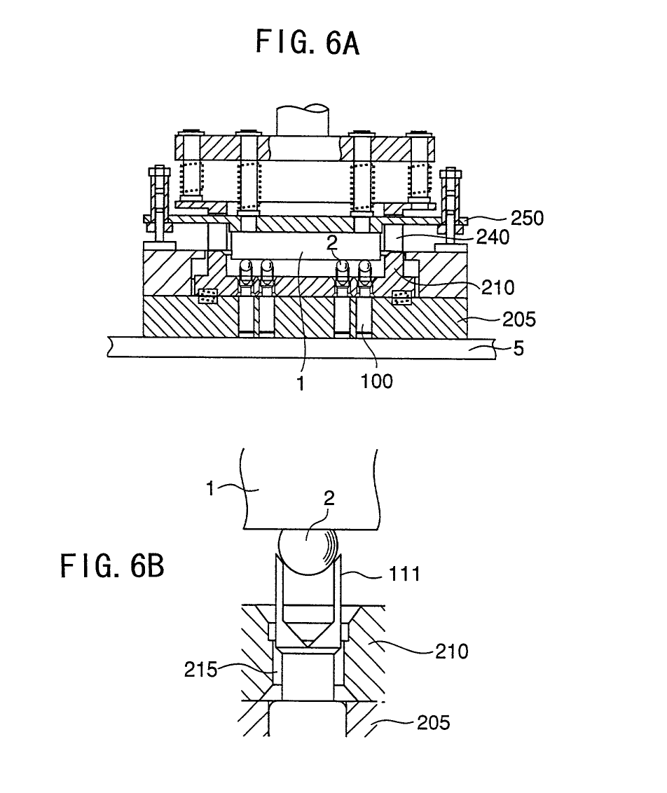

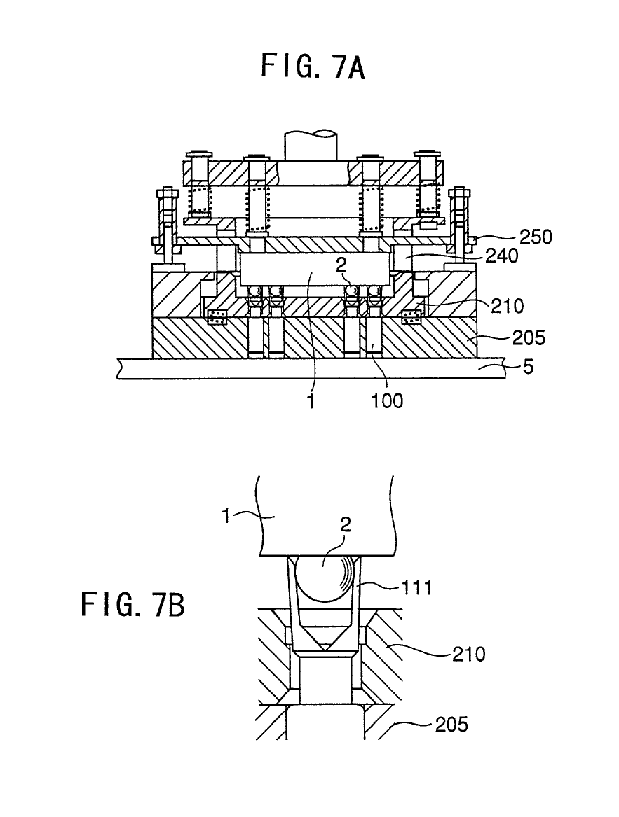

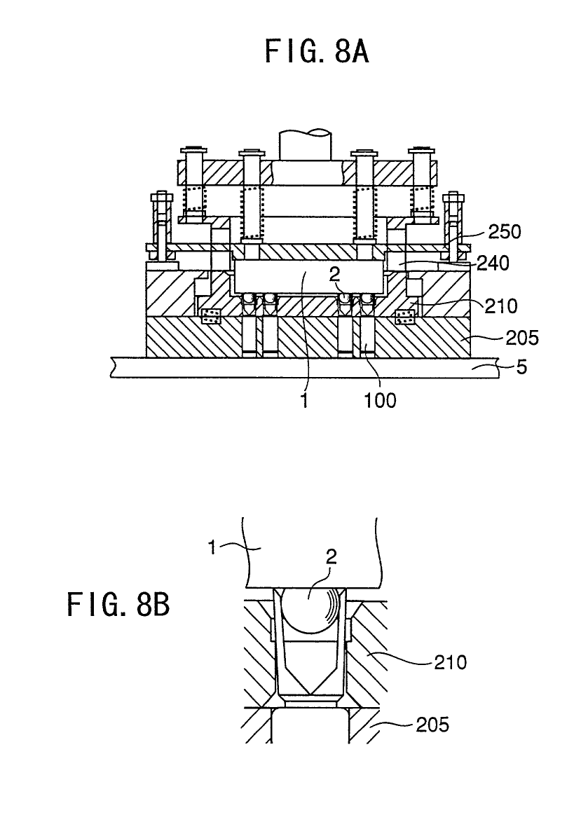

FIG. 5A is a sectional view of the IC contactor 200 and the IC package 1 in a state immediately after the IC package 1 is mounted in the IC contactor 200. FIG. 6A is a sectional view of the IC contactor 200 and the IC package 1 in a state in which the solder balls 2 of the IC package 1 are placed on the respective top end holding portions 111. FIG. 7A is a sectional view of the IC contactor 200 and the IC package 1 in a first holding state in which the solder balls 2 are held by the respective top end holding portions 111. FIG. 8A is a sectional view of the IC contactor 200 and the IC package 1 in a second holding state in which the solder balls 2 are held more firmly by the respective top end holding portions 111 than in the first holding state. FIGS. 5B, 6B, 7B, and 8B are enlarged sectional views of one of the solder balls 2, a corresponding one of the top end holding portions 111, and a later-described cradle 210 serving as a receiving member for the IC package 1, showing their positional relations in the respective corresponding states.

According to FIG. 5A, the IC contactor 200 includes a pressing portion 200A and a contact portion 200B, in which the IC package 1 is mounted. The contact portion 200B is provided below the pressing portion 200A.

The contact portion 200B has the contact base 205 provided on its bottom side. The contact base 205 is formed of an insulating material. The wiring board 5 is fixed to the bottom surface of the contact base 205. The contact base 205 has a plurality of the through holes 204 formed in positions corresponding to the positions of the solder balls 2 of the IC package 1, which is connected to the IC contactor 200. The contact pins 100 are fixedly inserted into the respective through holes 204.

A cradle-locking frame 208 is fixed on the edge portion of the upper surface of the contact base 205. The cradle-locking frame 208 includes a restriction flange portion 209, which protrudes inward to restrict an upper limit of the range within which the cradle 210 can move up and down in a space formed by the cradle-locking frame 208. On the cradle-locking frame 208, there are provided guide pins 207, which guide the upward and downward movements of the pressing portion 200A and determine the amount of the downward movement thereof.

The cradle 210 has a contact flange 212 formed on the sides thereof. The contact flange 212 contacts the above-described restriction flange portion 209. On the bottom side of the cradle 210, there are provided floating springs 206, which press the cradle 210 in an upward direction. Therefore, without external force being applied to the cradle 210 in a downward direction, the contact flange 212 of the cradle 210 contacts the restriction flange portion 209 of the cradle-locking frame 208, which state is shown in FIG. 5A. However, when predetermined external force is applied to the cradle 210 in the downward direction, the cradle 210 moves down until the cradle 210 contacts the contact base 205.

The cradle 210 also has a plurality of connection holes 215 in positions corresponding to the positions of the through holes 204 formed in the contact base 205. That is, the positions of the connection holes 215 correspond to the positions of the solder balls 2 formed on the IC package 1. According to FIG. 5B, the top end holding portion 111 of the contact pin 100 can make relative upward and downward movements in the connection hole 215 formed in the cradle 210. When the IC package 1 is mounted in the cradle 210, the solder balls 2 fit into the respective connection holes 215 so as to be positioned.

According to FIG. 5B, a ball-guiding step portion 216 is provided on the upper portion of the connection hole 215. The ball-guiding step portion 216 restricts the position of the solder ball 2 to the upper portion of the connection hole 215, and guides the upward and downward movements of the top end holding portion 111. With the ball-guiding step portion 216 being provided, the solder ball 2 can be connected to the connection pin 100 with more reliability. In the state shown in FIG. 5B, the top end holding portion 111 does not contact the solder ball 2, and the solder ball 2 is positioned on the upper portion of the connection hole 215. That is, the IC package 1 is positioned in the cradle 210.

Next, a description will be given of the pressing portion 200A, which can approach or be separated from the contact portion 200B by moving up and down a shaft 231 by a driving source (not shown).

The above-mentioned shaft 231 is fixed on an upper base 230. First guide shafts 233 and second guide shafts 235 penetrate through the upper base 230 so that the upper base 230 can move up and down along the first and second guide shafts 233 and 235. A package-holding block 250 is fixed to the lower ends of the first guide shafts 233, and a cradle-holding block 240 is fixed to the lower ends of the second guide shafts 235. A buffer spring 234 is provided around each of the first guide shafts 233 between the lower end thereof and the upper base 230 so as to press the package-holding block 250 in a downward direction. A buffer spring 236 is provided around each of the second guide shafts 235 between the lower end thereof and the upper base 230 so as to press the cradle-holding block 250 in a downward direction. By thus forming a structure in which sets of the first guide shafts 233 and the buffer springs 234 and sets of the second guide shafts 235 and the buffer springs 236 are independently provided, and the package-holding block 250 and the cradle-holding block 240 can be independently moved, the top end holding portions 111 and the solder balls 2 can be connected step by step according to this embodiment.

On the edge portion of the package-holding block 250, there are provided a plurality of lower limit adjusting stoppers 255 in positions corresponding to those of the guide pins 207 provided on the cradle-locking frame 208. The lower limit adjusting stoppers 255 are hollow, and the guide pins 207 are inserted thereinto so that the upward and downward movements of the pressing portion 200A are guided. Bolts 256 are inserted into the respective lower limit adjusting stoppers 255 so as to restrict the upper limit positions of the respective guide pins 207. The vertical positions of the respective bolts 256 are adjusted by respective nuts 257 so that a load applied from the pressing portion 200A to the contact portion 200B can be properly changed.

FIGS. 6A and 6B show the state in which the solder balls 2 of the IC package 1 are placed on the respective top end holding portions 111. In FIG. 6A, the pressing portion 200A is moved down from its position shown in FIG. 5A so that the cradle-holding block 240 presses down the cradle 210 until the cradle 210 contacts the contact base 205. According to FIG. 6B, the solder ball 2 is placed on the top end holding portion 111 of the contact pin 100, which is a state right before the solder ball 2 is pressed into the top end holding portion 111. In this state, the lower surface of the package-holding block 250 is extremely close to or slightly contacts the upper surface of the IC package 1.

FIG. 7A shows the first holding state in which the pressing portion 200A is moved further down from its position shown in FIG. 6A, and the lower surface of the package-holding block 250 contacts the upper surface of the IC package 1 so as to press down the IC package 1. In this state, as previously described with reference to FIG. 2, the elastic force (holding force) of the top end holding portion 111 is set to be weak compared with the pressing force of the coil spring 130. Therefore, as shown in FIG. 7B, the solder ball 2 can be held easily by the top end holding portion 111 with a pressing force of approximately 5 g per contact pin, which is weak compared with the pressing force required in the conventional method. At this point, wiping is performed on the surface of the solder ball 2 by the top end holding portion 111.

Above-mentioned FIG. 7B shows the first holding state in which a first holding step is completed so that the solder balls 2 is held by the top end holding portions 111 in the IC contactor 200 according to this embodiment. In this first holding state, the contact pins 100 are basically connected to the corresponding solder balls 2. However, poor connections may be caused therebetween by variations in the size of the solder ball 2 and deviations between the actual and right formation positions of the solder balls 2. Therefore, according to this embodiment, the IC contactor 200 realizes more reliable connections between the contact pins 100 and the corresponding solder balls 2 by a second holding step which realizes the second holding state shown in FIGS. 8A and 8B.

FIG. 8A shows the second holding state in which the pressing portion 200A is moved further down from its position shown in FIG. 7A, and the lower surface of the package-holding block 250 presses the upper surface of the IC package 1 so that the lower surface of the IC package 1 presses the upper ends of the top end holding portions 111, causing the entire top end holding portions 111 to be inserted into the respective connection holes 215 formed in the cradle 210. In this state, as the top end holding portions 111 are inserted into the corresponding connection holes 215, the inner walls of the respective connection holes 215 function as pressing units to press the respective top end holding portions 111 from the outside thereof. Therefore, according to the second holding state shown in FIG. 8B, the solder ball 2 is held more strongly and firmly by the top end holding portion 111. In the second holding state shown in FIGS. 8A and 8B, the connecting portions 112 of the contact pins 100 are pressed down against the coil springs 130 to be accommodated within the sleeves 131. In order to realize this state, a pressing force of approximately 15 g per contact pin is required, which force is equal to or less than half of the conventional pressing force of 30 to 40 g.

As is apparent from the above description, the IC contactor 200 according to this embodiment can reliably perform the first holding step of preferentially pressing the solder balls 2 into the respective top end holding portions 111 and the second holding step of firmly holding the solder balls 2 by the top end holding portions 111, thus securing the connection between the IC package 1 and the IC contactor 200.

As wiping is performed on the surfaces of the solder balls 2 in the first holding step, the connections between the solder balls 2 and the contact pins 100 can be improved even if insulating oxide films are formed on the surfaces of the solder balls 2. The first holding step requires a pressing force considerably weaker than that required in the conventional method employing elastic contact pins. Therefore, a connection process can be safely performed without causing damage to, that is, without causing stress to or chip-cracks in, the fragile IC package 1. Further, a series of the steps shown in FIGS. 5A through 8B can be performed successively, thus realizing a simplified, high-speed connection process.

The present invention is not limited to the specifically disclosed embodiments, and variations and modifications may be made without departing from the scope of the present invention.

The present application is based on Japanese priority application No. 2000-133764 filed on May 2, 2000, the entire contents of which are hereby incorporated by reference.

What is claimed is:

1. A method of electrically connecting an IC package to an IC contactor, the method comprising the steps of:
(a) receiving and holding protrusion electrodes of the IC package by contact pins of the IC contactor; and
(b) applying a pressing force from outside of the contact pins to the protrusion electrodes so that the protrusion electrodes are held more firmly by the contact pins than in said step (a).

2. The method as claimed in claim 1, wherein said step (a) widens the contact pins as the contact pins contact surfaces of the protrusion electrodes so that the contact pins receive and hold the protrusion electrodes.

3. The method as claimed in claim 1, further comprising the step of:
(c) determining a position of the IC package in the IC contactor before said step (a).

4. The method as claimed in claim 2, further comprising the step of:
(c) determining a position of the IC package in the IC contactor before said step (a).

5. An IC contactor to which an IC package is connected, the IC contactor comprising:
a contact base;
contact pins provided on said contact base so as to correspond to protrusion electrodes formed on the IC package, said contact pins comprising:
first plungers which comprise holding portions provided on tops thereof for holding the protrusion electrodes; and
second plungers which contact a base for external connection; and
first pressing units which apply a pressing force to said holding portions from outside thereof.

6. The IC contactor as claimed in claim 5, wherein:
said first plungers are movable so as to get closer to and away from the protrusion electrodes; and
said holding portions elastically deform to hold the protrusion electrodes.

7. The IC contactor as claimed in claim 5, wherein:
said first and second plungers are pressed by second pressing units so as to be separated from each other; and
said holding portions widen when a pressing force of the second pressing units is applied to said respective first plungers.

8. The IC contactor as claimed in claim 5, further comprising:
a member for receiving the IC package, said member being movable in upward and downward directions with respect to said contact pins, wherein said contact pins contact the protrusion electrodes through connection holes formed in said member so that the protrusion electrodes are positioned to determine a position of the IC package.

9. The IC contactor as claimed in claim 7, further comprising:
a member for receiving the IC package, said member being movable in upward and downward directions with respect to said contact pins,
wherein said contact pins contact the protrusion electrodes through connection holes formed in said member so that the protrusion electrodes are positioned to determine a position of the IC package.

10. The IC contactor as claimed in claim 8, wherein said first pressing units are provided in predetermined positions in the connection holes.

11. The IC contactor as claimed in claim 9, wherein said first pressing units are provided in predetermined positions in the connection holes.

12. The IC contactor as claimed in claim 8, further comprising:
a pressing mechanism which presses down said member and the IC package step by step so that steps of receiving and holding the protrusion electrodes by the contact pins and pressing the protrusion electrodes by said first pressing units to hold the protrusion electrodes more firmly can be successively performed by moving down said member.

13. The IC contactor as claimed in claim 9, further comprising:
a pressing mechanism which presses down said member and the IC package step by step so that steps of receiving and holding the protrusion electrodes by the contact pins and pressing the protrusion electrodes by said first pressing units to hold the protrusion electrodes more firmly can be successively performed by moving down said member.
